(19) United States
(12) Patent Application Publication
(10) Pub. No.: US 2019/0200489 A1
(43) Pub. Date: Jun. 27, 2019

(54) CONTROLLING OPERATIONAL PARAMETERS OF A COOLING UNIT

(71) Applicant: MCMASTER UNIVERSITY, Hamilton (CA)

(72) Inventors: Fernando Martinez Garcia, Hamilton (CA); Ghada Badawy, Burlington (CA); Douglas Graham Down, Hamilton (CA)

(21) Appl. No.: 16/229,242

(22) Filed: Dec. 21, 2018

Related U.S. Application Data
(60) Provisional application No. 62/609,545, filed on Dec. 22, 2017.

(51) Int. Cl. H05K 7/20

(52) U.S. Cl. CPC H05K 7/20836; H05K 7/20736; H05K 7/20781

(57) ABSTRACT

A cooling unit having a liquid coolant flow through the cooling unit and a gas coolant flow through the cooling unit is controlled using a temperature signal representing a present temperature associated with equipment cooled by the cooling unit and a delayed-effect variable signal representing a variable having a potentially delayed impact on the temperature associated with the equipment cooled by the cooling unit. A thermal system model to which the temperature signal, the delayed-effect variable signal, the liquid coolant flow and the gas coolant flow are inputs is used to calculate a projected future temperature associated with the equipment. Responsive to the projected future temperature, coolant flow is adjusted to target the projected future temperature toward a set-point by adjusting the liquid coolant flow and the gas coolant flow. The delayed-effect variable signal may represent, for example, a processing workload or a current drawn by the equipment.

### CROSS-REFERENCE TO RELATED APPLICATION

The present application claims priority to U.S. Provisional Application No. 62/609,545 filed Dec. 22, 2017, the teachings of which are hereby incorporated by reference.

### TECHNICAL FIELD

The present disclosure relates to cooling units for cooling of equipment.

### BACKGROUND

Data center (DC) energy consumption has attracted a lot of attention in recent years. According to J. Koomey, “Growth in data center electricity use 2005 to 2010,” A report by Analytical Press, completed at the request of The New York Times, 2011, DC energy consumption ranges from 1.1% to 1.5% of total global electricity consumption, which also has a tendency to increase; see J. Whitney and P. Delforge, “Scaling up energy efficiency across the data center industry: Evaluating key drivers and barriers,” NRDC, Issue Paper No. IP 08-14-A, August 2014, pp. 1-35. A significant portion of this energy utilization is devoted to cooling systems that aim to keep server temperatures within a safe region, necessary to avoid damage to servers. The safe temperature ranges for different classes of equipment are provided by guidelines such as those of ASHRAE, “ASHRAE TC9.9”, from Data Center Power Equipment Thermal, 2011, p. 11. Traditionally in DCs, cooling infrastructure is either room-based or row-based; see M. K. Patterson, “The Effect of Data Center Temperature on Energy Efficiency,” in 2008 11th Intersociety Conference on Thermal and Thermomechanical Phenomena in Electronic, Orlando, 2008 and K. Dunlap and N. Rasmussen, “Choosing Between Room, Row, and Rack-based Cooling for Data Centers,” in Schneider Electr. White Paper, 2012 (“K. Dunlap et al.”).

However, in recent years rack mountable cooling units have been introduced to cope with the increasing demand for high performance computations (HPC). These new cooling units bring servers and cooling units closer to each other with an aim to decrease cooling infrastructure energy consumption; see K. Dunlap et al.

In addition to reducing energy consumption, maintaining a stable temperature inside a data center is one of the most important requirements since constant oscillations in cold air temperature, even by 1 or 2 degrees, increases the probability of server failures; see N. El-Sayed, I. Stefanovici, G. Amvrosiadis and H. Andy A., “Temperature Management in Data Centers: Why Some (Might) Like It Hot,” in 2012 ACM SIGMETRICS/International Conference on Measurement and Modeling of Computer Systems, London, 2012. These oscillations are an inherent characteristic of the ON/OFF or proportional integral derivative (RID) controllers which have been widely used in cooling infrastructure; see A. Afram and F. Janabi-Sharifi, “Theory and applications of HVAC control systems A review of model predictive control (MPC),” Building and Environment, vol. 72, pp. 343-355, 2014. Due to the proximity of the rack mounted cooling units to the servers, any variation in airflow created by these controllers, as a response to changes in workload, will be experienced immediately by the servers, which will consequently lead to higher server failure rates.

Model Predictive Control (MPC) could avoid these oscillations by estimating the behavior of the system using a fixed model approach. MPC implementation in DC has already been explored (see Q. Fang, J. Wang, and Q. Gong, “QoS-Driven Power Management of Data Centers via Model Predictive Control,” IEEE Transactions on Automation Science and Engineering, vol. 13, pp. 1557-1566, 2016) showing good results via simulations. Although MPC can handle a wide variety of problems (see M. Kheradmandi, P. Mhaskar, “Model predictive control with closed-loop re-identification,”. Computers & Chemical Engineering. 109:249-60, 2018), it usually requires the solution of an iterative optimization problem at all sample times, which makes it infeasible in real world deployments since it requires expensive advanced micro-controllers that can handle this computational effort in real-time. Moreover, mismatches due to fixed models in MPC could have negative effects on the performance of the system.

### SUMMARY

In one aspect, the present disclosure is directed to a method for controlling operational parameters of a cooling unit, wherein a coolant flow through the cooling unit comprises a liquid coolant flow through the cooling unit and a gas coolant flow through the cooling unit. The method comprises receiving, at a controller for the cooling unit, at least one temperature signal representing a present temperature associated with equipment cooled by the cooling unit and receiving, at the controller, at least one delayed-effect variable signal representing a delayed-effect variable associated with equipment cooled by the cooling unit. The method further comprises calculating, by the controller, using a thermal system model to which the temperature signal(s), the delayed-effect variable signal(s), the liquid coolant flow and the gas coolant flow are inputs, a projected future temperature associated with the equipment cooled by the cooling unit, and responsive to the projected future temperature, adjusting coolant flow through the cooling unit to target the projected future temperature toward a set-point.

The thermal system model may include a cooling control function model for selectively cooperating the liquid coolant flow and the gas coolant flow to target the set-point according to an optimization parameter. The optimization parameter may be one of energy consumption and speed of set-point targeting. The thermal system model may be, for example, a static model or an adaptive model.

In some embodiments, the equipment cooled is information technology equipment, and the delayed-effect variable signal(s) comprise a processing workload signal representing an indication of a workload that will be assigned to the information technology equipment.

In some embodiments, the delayed-effect variable signal(s) comprise a current signal representing a current drawn by the equipment cooled by the cooling unit.

### BRIEF DESCRIPTION OF THE DRAWINGS

These and other features will become more apparent from the following description in which reference is made to the appended drawings wherein:

FIG. 1 shows, in schematic form, an illustrative test bed for an illustrative implementation of cooling according to an aspect the present disclosure;

FIG. 2 shows a two-dimensional representation of the possible infinite set of solutions that arise in the proposed approach when uⁱϵ [symbol] (left side of FIG. 2) and uⁱ∉ [symbol] (right side of FIG. 2);

FIG. 3 is a graph showing performance of an APC with standard GPC and an APC according to an aspect of the present disclosure when the random sinusoidal amplitude parameters of the water temperature are set to μ=0.4° C. and σ=0.3° C.;

FIG. 4 is a graph showing performance of an APC with standard GPC and an APC according to an aspect of the present disclosure when the random sinusoidal amplitude parameters of the water temperature are set to μ=0.145° C. and σ=0.11° C.;

FIG. 5 shows a block diagram representation of an illustrative control arrangement implemented on an illustrative system;

FIG. 6 is a graph comparing performance results for APC according to an aspect of the present disclosure to those for PID from an experiment using the test bed of FIG. 1 in which the top 12 servers were turned on, the bottom servers turned off and the air ducts of the latter blocked;

FIG. 7 is a graph comparing PWM manipulation of an APC according to an aspect of the present disclosure to that for PID, with resolution of 1, within the range [35,255] (8 bit representation);

FIG. 8 is a graph comparing water flow manipulation of an APC according to an aspect of the present disclosure and PID, with resolution of 0.02, within the range [9,21];

FIG. 9 shows performance of APC according to an aspect of the present disclosure with monetary cost reduction APC_{$};

FIG. 10 shows cumulative monetary reduction through time as savings in percentage of APC with C_{$}(u(k)) enabled with respect to APC;

FIG. 11 shows an illustrative implementation of cooling according to an aspect of the present disclosure similar to that in FIG. 1 but with a current signal as an additional input to the thermal system model;

FIG. 12 shows an illustrative implementation of cooling according to an aspect the present disclosure similar to that in FIG. 1 but with a processing workload signal as an additional input to the thermal system model; and

FIG. 13 is a flow chart showing an illustrative method for controlling operational parameters of a cooling unit.

### DETAILED DESCRIPTION

The present disclosure describes a computationally inexpensive Adaptive Predictive Controller (APC) which is implementable on an over the shelf general purpose microcontroller. The proposed APC may incorporate a projected gradient-based algorithm, so that, unlike certain other low complexity controllers, the proposed APC can reduce power consumption and operating costs.

The proposed APC proactively acts to predict the behavior of the system and also adapts to new operating conditions by employing a dynamic model. The use of APC has been explored in a variety of applications through simulations (see R. Hedjar, “Adaptive Neural Network Model Predictive Control,” International Journal of Innovative, vol. 9, no. 3, pp. 1245 - 1257, 2013; V. Bobal, M. Kubalcik, P. Dostal and J. Matejicek, “Adaptive predictive control of time-delay systems,” Computers and Mathematics with Applications, vol. 66, p. 165-176, 2013; I. Mizumotoa, Y. Fujimoto and M. Ikejiri, “Adaptive output predictor based adaptive predictive control with ASPR constraint,” Automatica, vol. 57, pp. 152-163, 2015); T.-W. Yoon, & D. W. Clarke “Adaptive predictive control of the benchmark plant,” Automatica, vol. 30, pp. 621-628, 1994).

Nonetheless, the real time application of APC in DCs has not yet been addressed. The proposed APC controller is partially adapted from an APC formulation for Multi-Input Single-Output Systems (MISO), for a specific type of minimization cost function. This formulation is combined with a proposed variable prediction horizon algorithm to increase its ability to deal with time-varying systems. Additionally, the APC described herein adds a method to transform infeasible solutions computed by the predictive formulation into feasible solutions when there is at least one. Moreover, predictive constraints based on general knowledge of the system are added to cope with transitory adaptation to the system. A variable forgetting factor algorithm for the adaptive method is described, so that the learning rate associated with new data varies according to the dynamics of the system. This is combined with an algorithm to avoid numerical instability when the adaptive algorithm faces low system excitation.

### Illustrative Hardware System Description

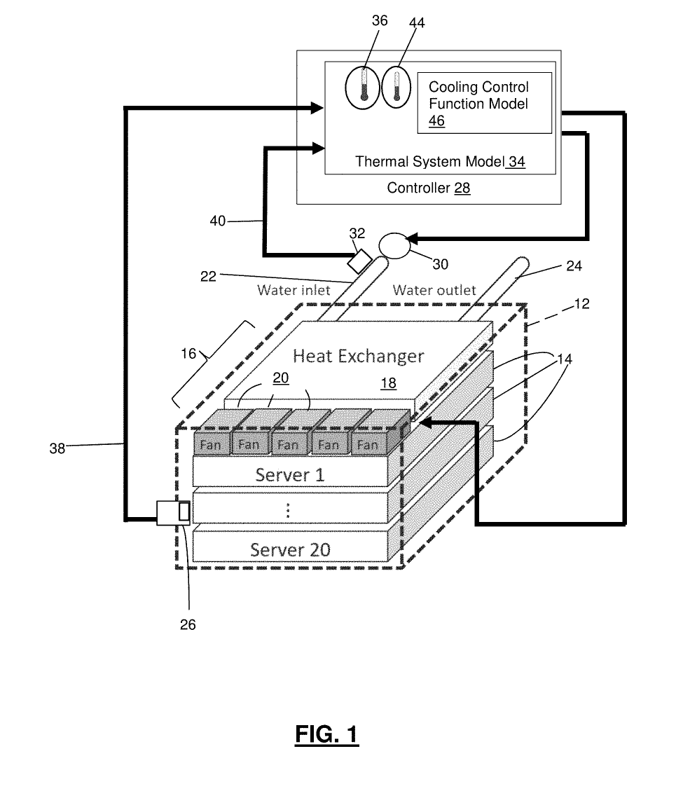

Broadly speaking, the present disclosure is directed to the cooling of equipment by way of one or more cooling units in which the cooling unit includes a heat exchanger, at least one liquid flow control element adapted to control flow of liquid coolant through the heat exchanger, and at least one gas flow control element adapted to control flow of gas coolant across the heat exchanger. FIG. 1 shows, in schematic form, an illustrative system, indicated generally at reference 10, used as a test bed for the present disclosure. The system 10 consists of a single rack 12 containing twenty (20) servers 14 with an average maximum power consumption of 250W per server, and a rack-mounted cooling unit 16 located at the top of the rack 12. The illustrative cooling unit comprises a heat exchanger 18, for example a plate-fin heat exchanger, and a set of five identical compact industrial fans 20; this is merely one illustrative example and is not intended to be limiting. Liquid coolant flows into the heat exchanger 18 by way of an inlet pipe 22 and flows out of the heat exchanger 18 by way of an outlet pipe 24. Thus, a coolant flow through the cooling unit 16 comprises a liquid coolant flow through the cooling unit 16, particularly the heat exchanger 18, by way of the inlet pipe 22 and the outlet pipe 24, and a gas coolant flow through the cooling unit by way of the fans 20. In the illustrated embodiment, the liquid coolant is water and the gas coolant is ambient air; in other embodiments other suitable types of liquid coolant and gas coolant may also be used. Construction of a suitable cooling unit is within the capability of one skilled in the art and is not described further.

The controlled variable is a temperature associated with the system or equipment to be cooled. Thus, at least one temperature sensor adapted to sense a temperature associated with equipment to be cooled by the cooling unit is provided. In the illustrated embodiment temperature is measured using a temperature sensor 26 of 0.06° C. resolution and located in front of the 12^{th} server 14 from the cooling unit 16, which is the hottest relevant point in front of the rack 12 in the illustrated embodiment. In other embodiments, other locations and/or resolutions for the temperature sensor may be employed. The temperature sensor 26 monitors the temperature of the air in the rack 12, which is presently the preferred embodiment, although other temperatures may be measured (e.g. CPU temperature, chassis temperature, or other temperature, with appropriate model adjustment). Optionally, more than one temperature sensor may be provided, and these may provide a plurality of temperature signals. The manipulated variables are the water flow in the heat exchanger 18 and the pulse-width modulation (PWM) signals that drive rotation of the fans 20, which are controlled by a controller 28. In the illustrated embodiment, the fans 20 have a maximum power consumption of 168W per unit and are directly and uniformly manipulated by the controller 28 through 8-bit resolution PWM signals at 488 Hz. Thus, the controller 28 for the cooling unit receives a temperature signal temperature sensor 26, representing a present temperature associated with the equipment, in this case the servers 14, cooled by the cooling unit 16. Optionally, where multiple temperature sensors are provided, the temperature signals may be preprocessed by a sub-processor into a single signal before being sent to the controller, or may be mathematically processed (e.g. average or weighted average) by the controller to provide an indication of the present temperature associated with the equipment.

In the illustrated embodiment, the water flow in the heat exchanger 18 is regulated by an adjustable valve 30. In the illustrated embodiment, the valve 30 is a ball valve whose aperture is changed by a local feedback loop model-based algorithm which generates electric pulses to manipulate the aperture, although other types of valve may be used. Hence, the input to the latter algorithm is the desired value of water flow calculated by the controller 28, which is coupled to the valve 30. In the illustrated embodiment, the water flow, with a maximum value near 21 L/min, is measured by a sensor 32 with average resolution of 1.06 L/min whose value is fed back to the water regulation algorithm; other sensors and/or resolutions may be used. In the illustrated embodiment, water is supplied by a branch of the building's water system, and its temperature is regulated by an outside controller (not shown) using cooling tower technology. Since the outside controller is not designed for delivering constant water temperature, there are changes in the water inlet temperature of the heat exchanger 18 in the system 10, which can have significant impact on the system. Therefore, the water inlet temperature is considered as a disturbance for the system. In other embodiments, water or other coolant may come from a dedicated supply, which may have greater precision with respect to temperature.

The controller 28 uses a thermal system model 34 to calculate a projected future temperature 36 of the equipment (e.g. servers 14) cooled by the cooling unit 16. The thermal system model 34 may be a static model or a dynamic model, and preferably is an adaptive model, for example an adaptive predictive model as described below. A temperature signal 38, a liquid coolant flow signal 40 and a gas coolant flow signal 42 are inputs to the thermal system model 34. The liquid coolant flow signal 40 and the gas coolant flow signal 42 may be actual flow measurements, e.g. the liquid coolant flow signal 40 from the flow sensor 32, or may be surrogate/proxy values, for example PWM or fan speed as a proxy for gas coolant flow. In response to the projected future temperature 36, the controller 28 adjusts the coolant flow through the cooling unit 16 to target the projected future temperature 36 toward a set-point 44. For example the controller 28 may compare the projected future temperature 36 to the set-point 44. Adjustment of the coolant flow through the cooling unit 16 by the controller 28 may comprise adjusting the liquid coolant flow and the gas coolant flow independently of one another, or there may be a mathematical relationship between the liquid coolant flow and the gas coolant flow.

The thermal system model 34 may include a cooling control function model 46 for selectively cooperating the liquid coolant flow and the gas coolant flow to target the set-point 38 according to an optimization parameter, which may be, for example, minimization of energy consumption, maximization of speed of set-point targeting, or another parameter.

The above-described server rack 12 and cooling unit 16 are merely illustrative embodiments provided for the purpose of illustration, and are not intended to be limiting in any way. Other configurations of server racks and cooling units may also be used. Moreover, while the present technology is well-suited to information technology equipment (ITE) applications and hence an illustrative implementation is described in respect of a server rack, the present technology is not so limited, and may be used in cooling applications generally.

Implementation of an exemplary thermal system model will now be described.

### Adaptive Predictive Controller (APC) Formulation

One illustrative formulation for an APC is based on the Weighted Recursive Least Squares (WRLS) and Generalized Predictive Controller (GPC) algorithms. The characteristics of both algorithms will now be briefly described.

### Weighted Recursive Least Squares.

The classic WRLS algorithm estimates the parameters of a plant with the following form: ŷ(k)=φ^{T}(k)θ(k), where φ(k)ϵ [symbol] ⁿ denotes the vector of outputs or measured variables, and θ(k)ϵ [symbol] ⁿ is the current estimate of the coefficients. The general objective of the algorithm is to recursively update the value of θ(k) to minimize the modeling error: J(k)=Σᵢ₌₀^{∞}λⁱê²(k−1), where ê(k−1) is the error between the actual, y(k−1), and the estimated, ŷ(k−1), outputs and λϵ(0,1] is a forgetting factor used to place greater emphasis on recent errors. The WRLS algorithm is summarized in equations (1)-(3).

$$\begin{matrix}θ ( k ) = θ ( k - 1 ) + G ( k ) ( y ( k ) = {ϕ}^{T} ( k ) θ ( k - 1 ) ) , & ( 1 ) \\ G ( k ) = \frac{P ( k - 1 ) ϕ ( k )}{λ + {ϕ ( k )}^{T} P ( k - 1 ) ϕ ( k )} , & ( 2 ) \\ P ( k ) = \frac{P ( k - 1 ) - G ( k ) {ϕ ( k )}^{T} P ( k - 1 )}{λ} , & ( 3 )\end{matrix}$$

where P(k)ϵ [symbol] ^{n×n} is the inverse of the estimated covariance matrix, denoted as M(k), around 0ϵ [symbol] ⁿ and G(k)ϵ [symbol] ⁿ is the gradient descent direction, also known as the gain vector used to update θ(k). When there is initial information available, the value of θ(0) and P(0) can be computed using a standard least squares algorithm. Otherwise, they are initialized as θ(0)=0 and P(0)=cI, where c≥1 and I is the identity matrix.

### Generalized Predictive Controller

The GPC algorithm can be traced back to D. W. Clarke, C. Mohtadi and P. S. Tuffs, “Generalized Predictive Control Part II. Extensions and Interpretations*,” Automatica, vol. 23, no. 2, pp. 149-160, 1987 and D. W. Clarke, C. Mohtadi and P. S. Tuffs, “Generalized Predictive Control Part I. The Basic Algorithm,” Automatica, vol. 23, no. 2, pp. 137-148, 1987 (collectively, “D. W. Clarke et al.”), and has been a popular predictive control algorithm, with a wide variety of applications. For a MISO system with m inputs, considering a prediction horizon γ and a control horizon γ_{c}≤γ, the forecasted behavior of the system ŷ(k+γ|k) made by the GPC can be summarized in equations (4) and (5).

\hat{y}(k+γ|k)=Ayₚₐₛₜ(k)+Buₚₐₛₜ(k)+Hu_{future}(k) (4)

or the most commonly used

$$\begin{matrix}\hat{y} ( k + γ \vert k ) = {Ay}_{past} ( k ) + {Bu}_{past} ( k ) + {H}_{r} u ( k ) + G Δ {u}_{future} ( k ) , & ( 5 ) \\ where & \\ \hat{y} ( k + γ \vert k ) = [ \begin{matrix}\hat{y} ( k + 1 ) \\ ⋮ \\ \hat{y} ( k + γ )\end{matrix} ] , {y}_{past} ( k ) = [ \begin{matrix}\hat{y} ( k ) \\ ⋮ \\ \hat{y} ( k - a )\end{matrix} ] , & \\ {u}_{past} ( k ) = [ \begin{matrix}{u}_{1} ( k ) \\ ⋮ \\ {u}_{m} ( k )\end{matrix} ] {u}_{j} ( k ) = [ \begin{matrix}{u}_{1} ( k ) \\ ⋮ \\ {u}_{m} ( k - {b}_{j} )\end{matrix} ] , & \\ {u}_{future} ( k ) = [ \begin{matrix}u ( k + 1 ) \\ ⋮ \\ u ( k + {γ}_{c} )\end{matrix} ] , u ( k + j ) = [ \begin{matrix}{u}_{1} ( k + j ) \\ ⋮ \\ {u}_{m} ( k + j )\end{matrix} ] , & \\ u ( k ) = [ \begin{matrix}{u}_{1} ( k ) \\ ⋮ \\ {u}_{m} ( k )\end{matrix} ] , Δ {u}_{future} ( k ) = [ \begin{matrix}Δ u ( k + 1 ) \\ ⋮ \\ Δ u ( k + {γ}_{c} )\end{matrix} ] , & \\ Δ u ( k + j ) = [ \begin{matrix}Δ {u}_{1} ( k + j ) \\ ⋮ \\ Δ {u}_{m} ( k + j )\end{matrix} ] & \end{matrix}$$

The values a and bⱼ represent the number of previous instances of the output and input j, respectively. The matrices Aϵ [symbol] ^{γ×a}, Bϵ [symbol] ^{y×m(b}^{₁}^{+ . . . +b}^{ₘ}⁾, H and Gϵ [symbol] ^{γ×(m·γ}^{_{c}}⁾ can be obtained using the recursive formulation given in D. W. Clarke et al. Part II, and Hᵣϵ [symbol] ^{γ×m} is a submatrix of G. Also, it is important to mention that, as illustrated in D. W. Clarke et al. Part II, H and G are lower block triangular matrices with the same structure, shown in equation (6), where gⱼϵ [symbol] ^{1×m}.

$$G = [ \begin{matrix}{g}_{1} & {0}^{1 \times m} & … & {0}^{1 \times m} \\ {g}_{2} & {g}_{1} & ⋱ & ⋮ \\ ⋮ & {g}_{2} & ⋱ & {g}_{1} \\ ⋮ & ⋮ & ⋱ & ⋮ \\ {g}_{γ} & {g}_{γ - 1} & … & {g}_{γ - {γ}_{c} + 1}\end{matrix} ] \qquad ( 6 )$$

By considering the current conditions of the system, the GPC algorithm can compute the future values of the manipulated variables, so that the predicted behavior of the system closely tracks a desired vector of set-points wϵ [symbol] ^{γ}, i.e. ŷ(k+γ|k)≈w. The input sequence is computed by minimizing the cost function shown in equation (7) whose analytical solution is given by equation (8).

J(k)=(w−ŷ(k+γ|k))^{T}Q(w−ŷ(k+γ|k))+Δu_{future}^{T}(k)RΔu_{future}(k) (7)

Δu_{future}(k)=(G^{T}QG+R)⁻¹G^{T}Q(w−Ayₚₐₛₜ(k)−Buₚₐₛₜ(k)−Hᵣu(k)) (8)

The matrices Q,Rϵ [symbol] ^{γ×γ} are positive semi-definite block diagonal matrices that assign weights to future errors and penalize the input rate of change. It is important to note that like most predictive-based algorithms, GPC is of receding-horizon form, which implies that at each sampling time the value of the sequence u_{future}(k) is recomputed.

When the control horizon γ_{c} is set to 1, only one increment in the inputs is considered, after which no further changes will be implemented, implying that a constant input u will be held during the prediction horizon. In this case, since u(k+j)=u, ∀j≤γ_{c}, using (6) the matrix G is reduced to [g₁^{T} . . . g_{γ}^{T}]^{T} and the complexity of computing equation (8) is significantly decreased.

In D. W. Clarke et al. Part II it is explained that the selection of u made by the GPC algorithm when γ_{c}=1 would be the optimal “mean-level” controller that places the system output close to the set-point. Hence, for stable systems with possible dead-time, γ_{c}=1 in general would compute a near optimal solution due to the receding-horizon approach of the GPC algorithm.

The next portion of the disclosure describes a novel APC which combines the previous formulation with the use of a variable forgetting factor and a variable prediction horizon for a specific case of the GPC algorithm. This portion of the disclosure also describes how various specific implementation issues can be handled within the proposed framework when there is low excitation or richness of data in the RLS algorithm, which can lead to poor performance and computational instability. In addition, the modified formulation is compared against classical formulations in simulation. Then, the proposed controller algorithm is implemented in a low-cost microcontroller which is installed in the illustrative cooling system described above. The novel APC is integrated with a monetary cost reduction function within the predictive formulation framework. Finally, the performance of the proposed framework is compared with the nominal approach.

### Formulation Changes

### (1) Variable Forgetting Factor

The idea of a variable forgetting factor has been addressed in W. W. Woo, S. A. Svoronos and 0. D. Crisalle, “A Directional Forgetting Factor for Single-Parameter Variations,” in Proceedings of the American Control Conference, Seattle, 1995, A. K. Rao and Y.-F. Huang, “ARMA Parameter Estimation Using a Novel Recursive Estimation Algorithm with Selective Updating,” IEEE Transactions on Acoustics, Speech, And Signal Processing, vol. 38, no. 3, pp. 447-457, 1990 and S. Bittanti and P. C. M. Bolzern, “Convergence and Exponential Convergence of Identification Algorithms with Directional Forgetting Factor,” Automatica, vol. 26, no. 5, pp. 929-932, 1990. The approach described herein is simpler compared to these previous methods, making it easier to implement but at the same time robust enough, by avoiding overfitting too few samples. For a variable forgetting factor, two important points should be considered. First, it should be able to be maintained close to 1, so that the adaptive error is low enough that relevant information is not lost. Secondly, it should avoid values too close to 0, to avoid overfitting new data.

The proposed variable forgetting factor, λ(k), considers these points by introducing three constraints. First, a minimum time window wₘᵢₙ of information is enforced. Secondly, a maximum adaptive error êₘₐₓ and, finally a minimum adaptive error êₘᵢₙ are introduced, so that ê(k)≥êₘₐₓ will imply that λ(k) will be assigned a minimum value, λₘᵢₙ. The method will forget previous data but will remember at least the information from the previous wₘᵢₙ sampling times. Also, ê(k)≤êₘᵢₙ implies that λ(k)≈1. Next, the present disclosure describes how these ideas are implemented, omitting k to simplify notation when possible.

First, note that in the cost function of the WRLS algorithm, the factor λⁱ is the weight associated with ê²(k−i). Hence, it is not difficult to see that the first m terms have a weight of

$$\frac{1 - {λ}^{m + 1}}{1 - λ}$$

and the remainder

$$\frac{λ m + 1}{1 - λ} ,$$

or relative proportion 1−λ^{m+1} and λ^{m+1}, respectively. Note that it is possible to assign a minimum desired fraction pₘᵢₙ to the last terms with a minimum desired time window wₘᵢₙ so that

$$λ \geq {λ}_{min} = {( {p}_{min} )}^{\frac{1}{r}} ,$$

where

$$r = \frac{{w}_{min}}{{T}_{sampling}}$$

and T_{sampling} is the sampling period. This can be done by using a monotonically decreasing function f(ê)≥1 that satisfies equation (9).

λ^{f(ê)}=λₘᵢₙ (9)

The function f(ê) should be able to rapidly reach a maximum value, denoted by K, when ê is “close” to êₘᵢₙ so that λ≈1 and also, it should be capable of rapidly reaching a value close to 1 when ê is close to êₘₐₓ. Based on these properties, f(ê) is chosen as in equation (10), which allows the time window to be extended as appropriate.

$$f ( \hat{e} ) = {K}^{( \frac{\hat{e} - {\hat{e}}_{min}}{{\hat{e}}_{max} - {\hat{e}}_{min}} )} \qquad ( 10 )$$

As desired, f(ê) has a minimum value of 1 and a maximum value of K. Also, note that λ^{f(ê)r}=pₘᵢₙ, from this it is possible to conclude that Kwₘᵢₙ represents the maximum time window considered in the algorithm, which implies that for λ approaching 1, K does not need to be too large, simplifying the computation of λ.

Since redundant information should be avoided, to make P(k) computationally stable (avoid numerical overflow), an additional parameter ê_{z} was added so that the adaptive algorithm is executed only when ê_{z}<ê, otherwise θ(k)=θ(k−1) and P(k)=P(k−1). Here, ê_{z} represents the acceptable adaptive error below which no information needs to be added to the adaptive algorithm.

### (2) Variable Prediction Horizon.

The idea of using a variable prediction horizon in MPC has been addressed; see R. C. Shekhar and J. M. Maciejowski, “Robust variable horizon MPC with move blocking,” Systems & Control Letters, vol. 61, pp. 587-594, 2012 and S. S. KEERTH and E. GILBERT, “Optimal Infinite-Horizon Feedback Laws for a General Class of Constrained Discrete-Time Systems: Stability and Moving-Horizon Approximations,” Journal of Optimization Theory and Applications, vol. 57, no. 2, pp. 265-293, 1988.

A variable prediction horizon for the GPC is described. Based on the formulation and assumptions of the GPC for a MISO system with m inputs, when the control horizon γ_{c} is set to 1, the computational cost of calculating Δu(k+1) is significantly decreased. However, this computation can be further simplified by setting all elements in R to one, and all elements in Q to zero except for the last element, which is set to 1. Under this specific case the cost function in equation (7) is simplified and can be solved to find an analytical solution in equation (11), with a solution for the corresponding control update given in equation (12).

$$\begin{matrix}{ℊ}_{γ} Δ u ( k + γ ) = {w}_{γ} - {a}_{γ} {y}_{past} ( k ) - {b}_{γ} {u}_{past} ( k ) - {ℊ}_{γ} u ( k ) & ( 11 ) \\ Δ u ( k + γ ) = \frac{{ℊ}_{γ}^{T}}{{ℊ}_{γ} {ℊ}_{γ}^{T}} ( {w}_{γ} - {a}_{γ} {y}_{past} ( k ) - {b}_{γ} {u}_{past} ( k ) - {ℊ}_{γ} u ( k ) ) & ( 12 )\end{matrix}$$

The main advantage of equation (12) is that it only considers the last set-point in the prediction horizon. Hence, it is important to select an appropriate prediction horizon γ, so that γ can be small enough to make the system achieve the desired set-point as fast as possible and, at the same time, large enough to avoid generating infeasible solutions u(k+1)∉ [symbol] . The latter tradeoff can be handled by exploiting the simplicity of equation (12).

From now on, (w_{γ}−a_{γ}yₚₐₛₜ(k)−b_{γ}uₚₐₛₜ(k)−g_{γ}u(k)) will be denoted as τ_{γ}, and it will be assumed that the set of feasible inputs [symbol] is a hyperbox. Then, by introducing a set of prediction horizons Γ={γₘᵢₙ, γₘᵢₙ+1, . . . , γₘₐₓ}, each Δuⁱ=Δu(k+i) corresponding to each iϵΓ can be computed using equation (12). Then, the set of elements [symbol] _{Δ}={Δu^{γ}^{ₘᵢₙ}, Δu^{γ}^{ₘᵢₙ}⁺¹, . . . , Δu^{γ}^{ₘₐₓ}} can be created, representing the control increment vectors obtained at prediction horizon values ranging from γₘᵢₙ to γₘₐₓ. For each element Δuⁱ=[Δu₁ⁱ, . . . , Δuₘⁱ]^{T} in [symbol] _{Δ} it is possible to compute its corresponding input uⁱ=[u₁ⁱ, . . . , uₘⁱ]^{T}. From here, there exist two cases that must be considered.

First, if the system has a single input, after computing uⁱ it is also necessary to compute uₛₐₜⁱ=SAT(uⁱ, uₘᵢₙ, uₘₐₓ), where SAT (⋅) is a function that saturates uⁱ so that uₘᵢₙ≤uₛₐₜⁱ≤uₘₐₓ. Then, the prediction horizon γ* is selected according to equation (13).

γ*=argmin_{iϵΓ}|τᵢ−gᵢuₛₐₜⁱ| (13)

In the case that there exists more than one element iϵΓ which minimizes |τᵢ−gᵢuₛₐₜⁱ|, the minimum value is selected for γ*. This selection is justified by the fact that the smallest elements of Γ will create less posteriori error with higher probability, since any small error between θ(k) and the ideal θ*(k) is propagated to A, B, H and G which are constructed recursively. Hence, the bigger j is, the bigger the mismatch in the prediction (with high probability).

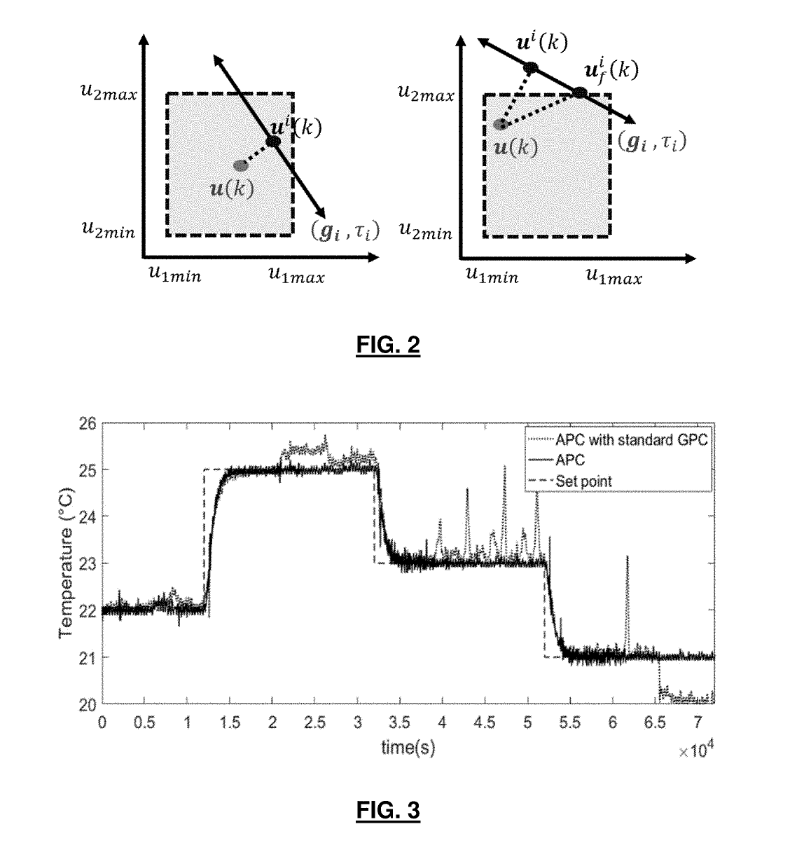

For the second case, when the system has more than one input and the solution obtained using the pseudo-inverse is not feasible i.e. uⁱ∉ [symbol] , it is possible to add one additional step before implementing the saturation function, in order to convert the vector uⁱ into a vector u_{f}ⁱ with the properties gᵢΔuⁱ=gᵢΔu_{f}ⁱand u_{f}ⁱϵ [symbol] . The latter process can be implemented by observing that the pair (gᵢ,τᵢ) represent the parameters of a hyperplane, the vertices of hyperbox [symbol] are defined by the closed intervals formed in (uₘᵢₙ, uₘₐₓ), and uⁱ=Δuⁱ+u(k), where u(k) is the solution implemented in the previous iteration of the algorithm. Hence, it is necessary to find a point in the hyperplane that is inside the boundaries of the hyperbox, as shown in FIG. 2, which shows a two-dimensional representation of the possible infinite set of solutions that arise in the proposed approach when uⁱϵ [symbol] (left) and uⁱ∉ [symbol] (right).

By observing FIG. 2 it is possible to identify that there can be an infinite number of candidate solutions for the value of u_{f}ⁱ, no solutions or one solution. When there are an infinite number of solutions, the main task is to select the closest solution to uⁱ so that the smallest feasible Δu_{f}ⁱ change in inputs can be achieved. In this way, the candidates are reduced to points in the intersection of the hyperplane and the hyperbox. First, the p faces of the hyperbox that are crossed are identified by using equation (14).

S={s|(1≤s≤m)∧([uⁱ]ₛ>[uₘₐₓ]ₛ∨[uⁱ]ₛ≤[uₘᵢₙ]ₛ)} (14)

Then, the hyperplane l of dimension m−p is defined by the pair (\check{g}ᵢ, \check{τ}ᵢ) where \check{g}ᵢ is the original vector gᵢ with components sϵS deleted and \check{τ}ᵢ=τᵢ−τ_{sϵS}[uₘᵢₙ₋ₘₐₓ]ₛ[gᵢ]ₛ, where uₘᵢₙ₋ₘₐₓ denotes either uₘᵢₙ or uₘₐₓ. Then, assuming at least one of the components of \check{g}ᵢ is non-zero, the vector Δu_{f}ⁱ that connects uⁱ to the closest point in l is computed using equations (15) and (16).

$$\begin{matrix}Δ {{u}^{⋁}}_{f}^{i} = \frac{{{ℊ}^{⋁}}_{i}^{T}}{{{ℊ}^{⋁}}_{i} {{ℊ}^{⋁}}_{i}^{T}} {\breve{τ}}_{i} & ( 15 ) \\ {[ Δ {u}_{f}^{i} ]}_{s} = {[ Δ {{u}^{⋁}}_{f}^{i} ]}_{s} , ∀ s ∉ S , {[ Δ {u}_{f}^{i} ]}_{s} = {[ {u}_{min - max} ]}_{s} , ∀ s ∈ S & ( 16 )\end{matrix}$$

Finally, using u_{f}ⁱ=uⁱ+Δu_{f}ⁱthe corrected solution can be calculated. If, after this process u_{f}ⁱ∉ [symbol] , then equations (14)-(16) are carried out again but this time using the hyperplane defined by the l parameters (\check{g}ᵢ, \check{τ}ᵢ) instead of (\check{g}ᵢ, τᵢ), so that the constraints already considered are not violated. Once this is carried out for each possible value of i, the set [symbol] ={i|iϵΓΛu_{f}ⁱ if exists} is created from which the prediction horizon γ* is obtained using equation (17).

γ*=min [symbol] (17)

If the set [symbol] is empty, due to no intersections between any hyperplane (\check{g}ᵢ, τᵢ) and the hyperbox [symbol] , implying infeasible inputs for the whole range [γₘᵢₙ, γₘₐₓ], then j is selected based on equation (13).

### 3) Low Excitation and Low Information Diversity

With the use of a variable forgetting factor, the WRLS algorithm is better at handling low excitation situations. However, this does not imply that the eigenvalues of the matrix P will be greater than zero at all sample times in practical implementations. Hence, two algorithms are described which can be implemented independent of each other creating an increase in the data diversity and assuring the eigenvalues of P will remain greater than zero.

First, it is observed that when there is a feasible solution Δuⁱ or modified feasible solution Δu_{f}ⁱ, there are usually an infinite number of solutions. Hence, when there exists steady state error (defined under some criterion), one can randomly select one of the solutions. This random selection can be implemented by finding all possible intersections between the edges of the hyperbox [symbol] and the hyperplane (gᵢ, τᵢ), and computing a random weighted average of them to select a new Δuⁱ which will be in the convex hull generated by the intersection. Looking for intersections at each edge for the case of m inputs would require 0(m2^{m-1}) iterations, which is manageable for small m. However, for m≥4 a more sophisticated algorithm such as the one in C. Lara, J. J. Flores and F. Calderon, “On the Hyperbox—Hyperplane Intersection Problem,” INFOCOMP, vol. 8, no. 4, pp. 21-27, 2009 can be implemented. The steady state error identification criterion which is utilized in this work considers a weighted average of the last kₛ errors.

The second algorithm keeps track of the trace of the matrix P, since the lack of diversity in φ could create a situation in which some of the eigenvalues of the covariance matrix M become close to zero due to hardware resolution. Hence, given a minimum eigenvalue μₘᵢₙ (defined by the user and hardware-dependent), if

$$Tr ( P ) \geq \frac{m}{{μ}_{min}}$$

then a multiple of the identity matrix cI is “injected” so that c≥μₘᵢₙ and P′=D(cI+μ)⁻¹D^{T}, where DμD^{T} is the spectral decomposition of M. The “injection” of cI into P can easily be done by running the step of the WRLS algorithm given in (3)m times, with λ=1 and using each of the m rows of cI as input to the algorithm.

### 4) Knowledge-Based Output and Predictive Constraints.

One of the main issues with the adaptive algorithm in the APC approaches is that, even when the adaptive error is close to zero, the use of a limited amount of information can generate coefficients θ(k) which do not necessarily represent the true dynamics of the system, which in turn can have a significant impact on the performance of the predictive algorithm. Therefore, there are two options that can be considered to avoid this problem, constraining θ(k) to a specific space or establishing constraints for gᵢ in the predictive algorithm. Without foreclosing the use of the former, the present disclosure will focus on the latter.

Typically, the output of the system is physically constrained so that yₘᵢₙ≤y(k)≤yₘₐₓ(k), ∀k. Hence, in the predictive algorithm, the following constraint is imposed: vᵢ=SAT(aᵢyₚₐₛₜ(k)+bᵢuₚₐₛₜ(k)+gᵢu(k),yₘᵢₙ,yₘₐₓ) and rᵢ=wᵢ−vᵢ. In addition, since (11) captures in gᵢ the physical effect that each manipulated variable has on the output, it is possible to constrain the values of g by setting gᵢ^{c}=SAT(gᵢ, gₘᵢₙ, gₘₐₓ).

Even when gₘᵢₙ and gₘₐₓ are not known, most industrial plants do have a minimum and maximum gain for each input variable, as a result of physical constraints. Hence, by selecting these minimum and maximum possible gains a lower bound for the true gₘᵢₙ and an upper bound for the true gₘₐₓ, information can be obtained or estimated with much less effort by the user in general. Based on this, the negative effects of transitory lack of information and large perturbations that dramatically change the value of θ(k) in a sudden manner that propagate to gᵢ can be decreased.

For cases in which the sign of the gain of the manipulated variables is known and constant, constraining gᵢ can avoid counterintuitive controller actions that do not prevent achieving the desired set-point value but waste unnecessary energy. Such cases can occur for a multiple input system in which the output behavior of one variable can be attributed to multiple inputs, and limited information about the inputs create cases such as attributing positive effects to a negative effect which is compensated by other input variables.

### 5) Monetary Cost Reduction Algorithm.

Based on equation (11) it is possible to implement an algorithm that minimizes the monetary cost rate C_{$}(u(k)) of the manipulated variables. Assuming the monetary cost function is differentiable, the gradient descent algorithm can be implemented restricted to be orthogonal to (gⱼ^{c})^{T}. The resulting direction for minimizing C_{$}(u(k)) is then observed in (18).

$$- ∇ {C}_{\$} ( u ( k ) ) + \frac{{( {ℊ}_{j}^{c} )}^{T}}{{{ℊ}_{j}^{c} ( {ℊ}_{j}^{c} )}^{T}} {ℊ}_{j}^{c} ∇ {C}_{\$} ( u ( k ) ) \qquad ( 18 )$$

Even though formula (18) can be used at any of the controller operations, its use is suggested only when the system output has already settled around the desired set-point, so that more freedom is given to the trajectories described by u(k).

### Simulations

The proposed controller was first tested on a MATLAB® software simulation environment. MATLAB is a trademark of, and is available from, The MathWorks, Inc. having an address at 1 Apple Hill Drive, Natick, Mass. 01760-2098. The system considered for the simulations has similar characteristics to the physical experimental test-bed described above with reference to FIG. 1. The model is composed of independent linearized subsystems of water flow, water inlet temperature and PWM signals with respect to the output temperature of the system. Also, simulations of the controller replacing the above-described predictive algorithm according to the present disclosure with the original version of the GPC were performed. For this case the parameters of the GPC were set to γ_{c}=1, Q=R=1.

The parameters for both controllers were set as follows. For the adaptive algorithm, êₘᵢₙ=0.05, êₘₐₓ=0.2, ê_{z}=0.01, pₘᵢₙ=0.1, wₘᵢₙ=350s and μₘᵢₙ=0.001. The model considered 8 previous values of outputs and inputs for a total of 24 coefficients, since the water inlet temperature variable is not considered for the controllers. For both predictive algorithms the prediction horizons γ and γₘₐₓ were set to 24. This value was selected so that the performance of the APC with standard GPC is optimized. In addition, γₘᵢₙ was set to 8 and the output constraints were set to γₘᵢₙ=15, γₘₐₓ=35.

Since the restriction of gᵢ decreased the performance of standard GPC in simulations, it was implemented only in the proposed variable prediction horizon algorithm, where gₘᵢₙ and gₘₐₓ values set to

$$[ - \frac{0.2}{255} , - \frac{0.2}{30} ] and [ - \frac{10}{255} , - \frac{10}{30} ] ,$$

respectively. Random selection of inputs was implemented using the naive algorithm of looking at each edge since the number of inputs considered was low, 5 in this case. This approach was not compatible with standard GPC; therefore it was not implemented in that setting.

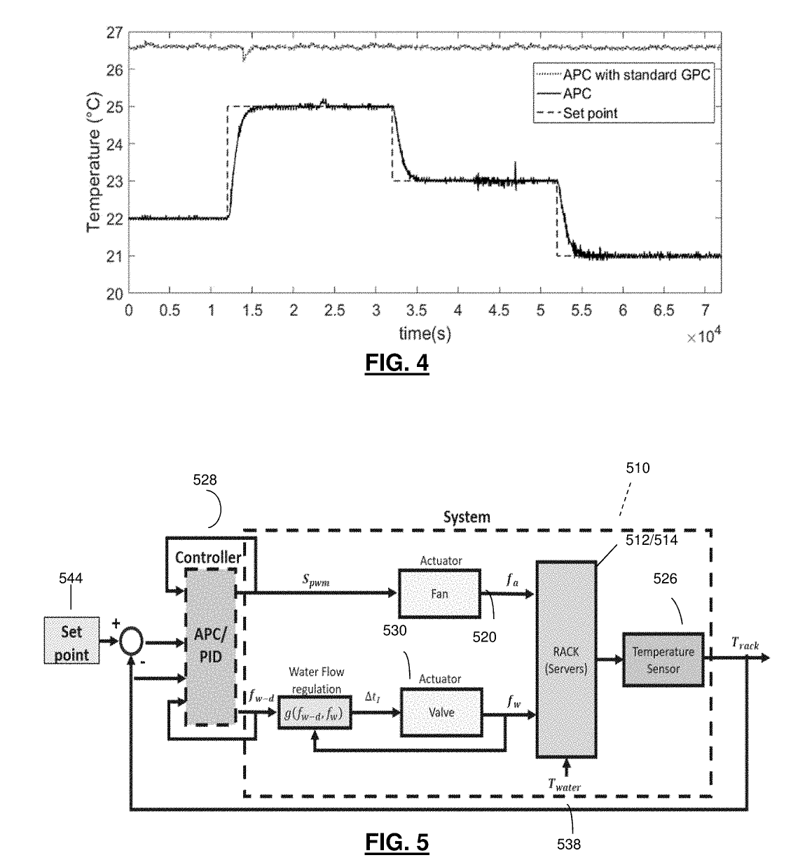

For the simulated system some additional physical restrictions were implemented. The output temperature was discretized to 0.06° C., which is identical to the resolution of the physical sensors used in the physical test-bed described above with reference to FIG. 1. Also, the water inlet temperature variable was set to a constant value of 12° C. plus a sinusoidal function with a period of 300s and bounded random amplitude. The water flow and PWM signal values calculated by the controllers were discretized to 0.02 L/min and 1 unit, respectively, and their variables were constrained to [100, 255] for PWM and [10, 27] for the water flow. Finally, a sampling time of 10 seconds was used. The results of the simulations are shown in FIG. 3 and FIG. 4. FIG. 3 shows performance of the APC with standard GPC and the above-described APC according to the present disclosure when the random sinusoidal amplitude parameters of the water temperature are set to μ=0.4° C. and σ=0.3° C. FIG. 4 shows performance of the APC with standard GPC and the above-described APC according to the present disclosure when the random sinusoidal amplitude parameters of the water temperature are set to μ=0.145° C. and σ=0.11° C. Thus, in FIG. 3, the random amplitude of the water sinusoidal component has a normal distribution with mean absolute value of 0.4° C. and standard deviation of 0.3° C. Similarly, in FIG. 4 those values were changed to 0.145° C. and 0.11° C., respectively.

The results observed in FIG. 3 indicate two relevant aspects. First, since the APC with standard GPC considers the entire set of values (hᵢ^{τ}, τᵢ), 1≤i≤γ, in an average-like approach, it tends to be slightly smoother than its counterpart. However, because it makes no individual analysis to identify which values (hᵢ^{τ}, τᵢ) could be generating infeasible solutions, it appears to be affected by them when such a case arises. In this aspect, since the above-described APC according to the present disclosure first identifies and discards the solutions that could generate this problem, it tends to provide better regulation.

Based on FIG. 4, it can be concluded that the task of correctly identifying the behavior of the system seems to be much more challenging for the APC with standard GPC. This can be deduced by observing that the reduction in the oscillations of the water temperature affected the performance of the algorithm, creating a situation in which it was not able to converge at all. On the other hand, the above-described APC according to the present disclosure copes well with the lack of frequency richness in the inputs and outputs.

The Mean Square Error of the simulation results for FIG. 3 and FIG. 4 can be found in Table 1 (see below) as Experiment 1 and Experiment 2, respectively.

### Experimental Results

The complete set of algorithms, including the valve manipulation, was implemented on an Arduino Mega microcontroller with 8KB of SRAM memory and 256KB of Flash memory, which proved to be more than enough for the current implementation, and about the same space needed by a standard APC with control horizon of 1. This is merely one example of a suitable controller which was used for experimental purposes, and is not intended to be limiting. Other suitable controllers, including but not limited to suitably-programmed general purpose computers and other processing devices, may also be used.

Note that even though the water regulation algorithm is encoded at the same level as the controller, this is transparent to the controller and is considered part of the physical system.

Based on the previous formulation and the practical changes implemented on it, some experiments were carried out on the single rack system. The algorithm was programmed on the Arduino Mega microcontroller using only 60% of the SRAM for static variables and about 30% for non-static variables, for a total of 90%. For all experiments the performance of the APC controller was compared against a multi-PID controller which was tuned for the temperature system. The multi-PID controller consists of independent single loop PM controllers for each of the manipulated variables. A general diagram of the implementation on the system of both controllers, APC and multi-PID, can be observed in FIG. 5, which shows a block diagram representation of the APC and PID controllers implemented on the system. As can be seen in FIG. 5, a set-point 544 is fed as input to a controller 528 for the system 510. The controller 528 also receives a temperature signal 538 from the temperature sensor 526 associated with the rack 512 and servers 514. The controller 528 in turn controls the fans 520 and the valve 530 that governs water flow.

The performance of the APC and multi-PID controllers was compared for the following system configuration. In the experiment the top 12 servers were turned on and the rest of them were turned off, the air ducts of the “off” servers were blocked to force the air to recirculate only through the “on” servers. The temperature sensor is allocated at the level of the lowest server which is on, which is also the location of the hottest temperature at the front of the system where the air recirculates. For this experiment no initial conditions were assumed, hence 400s were given to the APC to stabilize the output before the comparison was made.

The parameters for the APC were set as follows: êₘᵢₙ=0.045, êₘₐₓ=0.2, ê_{z}=0.001,pₘᵢₙ=0.1, wᵢₙ=150 and μₘᵢₙ=0.1. The 8 previous values of outputs and inputs yield a total of 24 coefficients. Also, γₘₐₓ=14, γₘᵢₙ=3, yₘᵢₙ=20, yₘₐₓ=40, gₘᵢₙ and gₘₐₓ values were set to

$$[ - \frac{0.2}{255} , - \frac{0.2}{30} ] and [ - \frac{10}{255} , - \frac{10}{30} ] ,$$

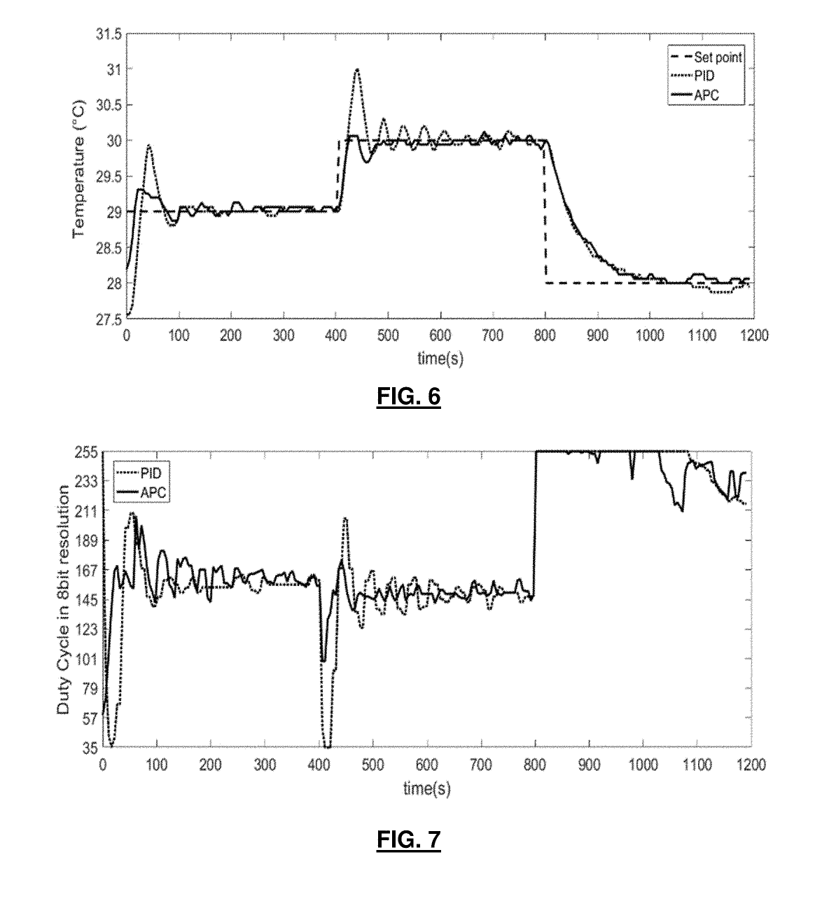

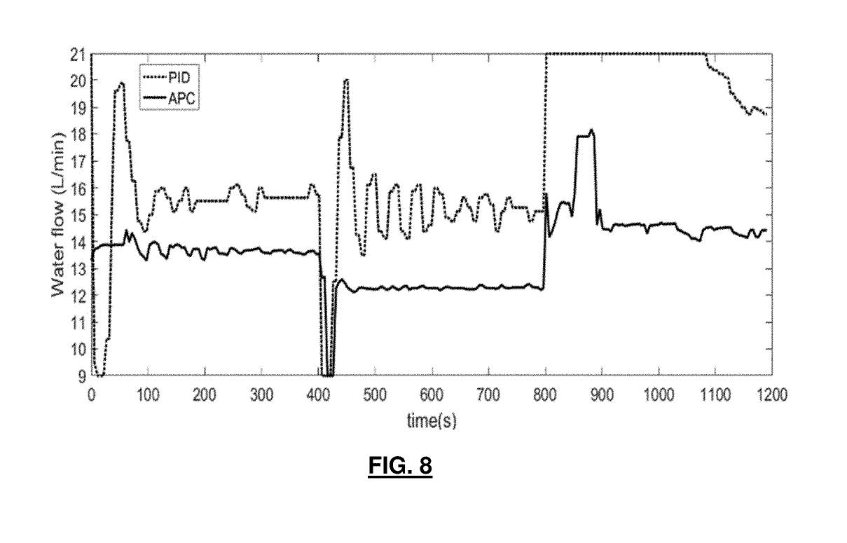

respectively. The water flow and PWM values calculated by the APC were discretized to 0.02 L/min and 1 unit. Finally, the manipulated variables were constrained to [35,255] for PWM and [9,21] L/min for water flow. The results of the experiment can be observed in FIGS. 6 to 8. FIG. 6 is a graph showing performance results for APC and PID from the above experiment, FIG. 7 is a graph showing PWM manipulation of APC and PID, with resolution of 1, within the range [35,255] (8 bit representation), and FIG. 8 is a graph showing water flow manipulation of APC and PID, with resolution of 0.02, within the range [9,21].

After the 400s gap, when the adaptive algorithm has obtained enough information, one can observe that the APC performance tends to be better than the multi-PID in FIG. 6, since it generates less overshoot when a new value for the set-point is established and it is still able to achieve the desired set-point. The decreased overshoot can be mainly attributed to the system behavior forecasting made by the predictive algorithm of the APC.

Because of the feedback relationship among the inputs and the predictive output, less oscillations occur in the manipulated variables, showing on average a more consistent behavior in the inputs for the APC algorithm. Finally, since the APC considers the effects of the manipulated variables on the output simultaneously and not independent of each other as the ND implicitly does, saturated behaviors on the inputs are also significantly decreased since a more accurate selection of their values is made.

Additional experiments were conducted to test the monetary cost reduction algorithm in formula (18). The monetary cost function of the manipulated variables for the current system have the form of c_{$}(u(k)=b_{$}u^{j}, where b_{$} contains the cost of the energy used by the fans and the cost of water per liter/min,

$${b}_{\$} = [ 5.94 ( {10}^{- 6} ) \frac{cents}{\cdot s} 6.340 ( {10}^{- 3} ) \frac{cents}{\frac{L}{min} s} ] . \qquad$$

These values were obtained by using information from the province of Ontario, Canada (O. E. Board, “Ontario Energy Board,” 2018 [Online] at https://www.oeb.ca/rates-and-your-bill/electricity-rates [Accessed 10 Jul. 2018] and City of Toronto, “2018 Water Rates & Fees,” 2018 [Online] at https://www.toronto.ca/services-payments/property-taxes-utilities/utility-bill/water-rates-and-fees/ [Accessed 10 Jul. 2018]).

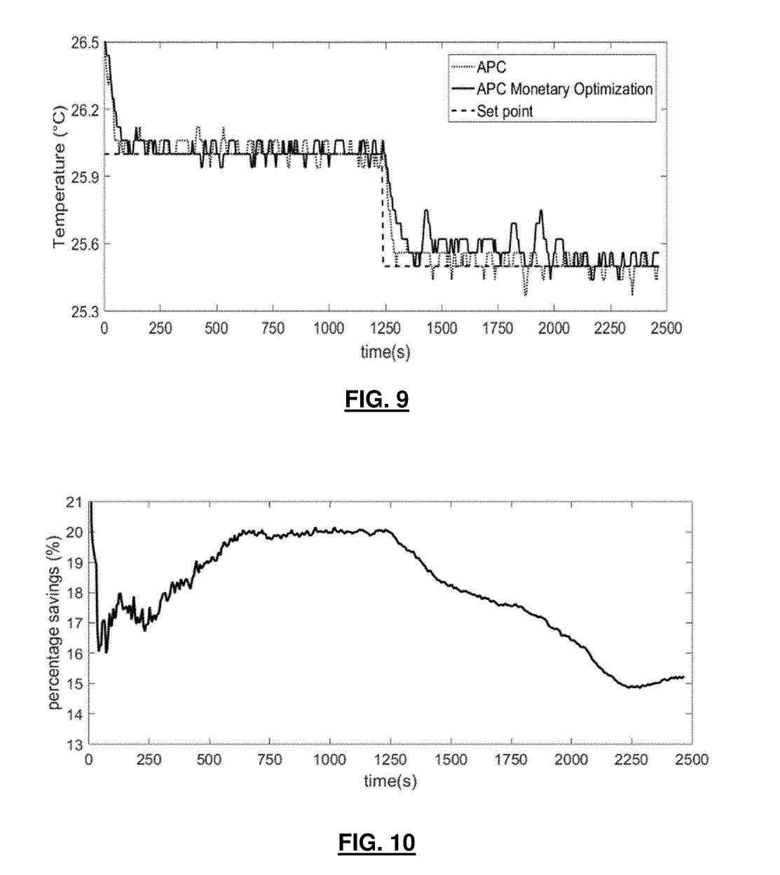

The monetary cost reduction algorithm was activated only when the system arrived at the desired set-point and remained stable for 4 iterations. The performance of the APC with the monetary cost reduction APCs, is shown in FIG. 9, and the cumulative monetary reduction through time is observed in FIG. 10, which shows savings in percentage of the APC with C_{$}(u(k)) enabled with respect to APC.

From FIG. 10 it is possible to observe that in the above experiment, APC_{$}, generated a reduction near 15% of C_{$}(u(k)) when compared to the APC, which could represent a significant saving for the user. Also, both APCs, and APC are similar in general performance. However, since the former slowly changes the state of the system by making small adjustments to u(k), it can become more vulnerable to disturbance effects caused by the water temperature, as observed in FIG. 9. Despite this, when the system changes the desired set-point the algorithm which minimizes C_{$}(u(k)) is not active until it returns to the set-point.

The Mean Square Error of the simulations' results for FIG. 6 and FIG. 9 can be found in Table 1 as Experiment 3 and Experiment 4, respectively.

TABLE 1
MSE index of the performance of the controllers during the experiments

| | Controller | MSE |
|---|---|---|
| Experiment 1 | standard | |
| | APC | 0.5611 |
| | APC | 0.4011 |
| Experiment 2 | standard | |
| | APC | 4.0564 |
| | APC | 0.3929 |
| Experiment 3 | PID | 0.4239 |
| | APC | 0.3650 |
| Experiment 4 | APC | 0.0814 |
| | APC_{$} | 0.1088 |

According to the foregoing description, an industrially feasible APC from economic and computational points of view was designed and implemented for temperature control in data centers. The proposed APC according to the present disclosure was compared against a nominal APC with similar computational cost via simulation and experiment. The simulation results indicated that improved performance was achieved on a constrained system. In order to calculate control action an economical microcontroller was utilized. The experimental results indicated that the proposed APC outperforms classical PIDs in particular in reducing the oscillations in the temperature and moderating changes in the manipulated variables. Also, an illustrative projected gradient descent-based algorithm was proposed to include monetary cost minimization to develop an APCs, controller. The experimental results of the proposed method indicated a reduction in the energy cost of the cooling unit with respect to the nominal APC.

### Additional Factors

An APC according to the present disclosure can be expanded to account for additional factors which may impact future temperature. For example, in a server rack, the current drawn by the servers, or the workload assigned to the servers, may be expected to affect the temperature, albeit with a delayed effect. Thus, workload and/or current, or other delayed-effect variables may be additional inputs into the APC.

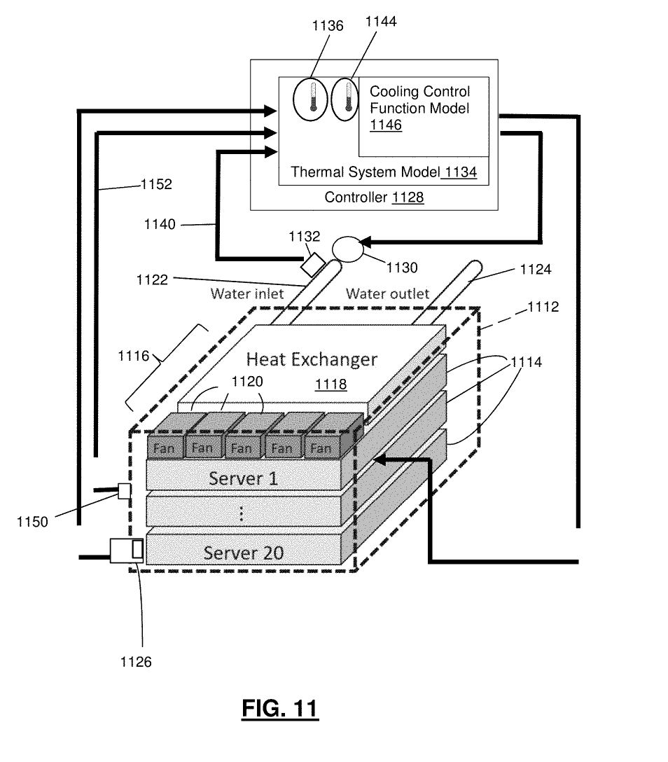

Reference is now made to FIG. 11, which shows an arrangement similar to FIG. 1, with like reference numerals denoting like features, except with the prefix “11”. A current sensor 1150 on the rack 1112 monitors current drawn by the servers 1114 and generates a current signal 1152 which is received at the controller 1128. The current signal 1152 represents a current drawn by the equipment (servers 1114 in this case) cooled by the cooling unit 1116, and is a further input to the thermal system model 1134. Optionally, current drawn by the servers 1114 can be measured indirectly. For example, the current signal may be, or be derived from, a CPU temperature for one or more of the servers 1114. CPU temperature is a reasonable proxy for current drawn by the server that includes that CPU. The current signal may be instantaneous current measured by a transducer, etc. or may be a measurement (with or without additional processing/calculation) by a thermocouple, thermistor, IR camera, or other suitable sensor.

The current will have a somewhat delayed effect on the measured temperature; the current will typically change faster and more frequently than the temperature and some changes in current may offset one another without materially effecting the temperature associated with the equipment. Because the current is expected to have a delayed effect on the temperature, it is preferred to modify the APC model to account for the delay.

As noted above, the classic WRLS algorithm estimates the parameters of a plant with the following form: ŷ(k)=φ^{T}(k)θ(k), where φ(k)ϵ [symbol] ⁿ denotes the vector of outputs or measured variables, and θ(k)ϵ [symbol] ⁿ is the current estimate of the coefficients. This equation can be detailed further in terms of the type of values contained in φ, as shown in equation (19):

\hat{y}(k)=ayₚₐₛₜ(k)+buₚₐₛₜ(k)+hu(k) (19)

where ŷ(k) is the output estimated behavior in the next iteration, ayₚₐₛₜ(k) is the past output behavior, buₚₐₛₜ(k) is the past manipulated inputs behavior and hu(k)is the current manipulated inputs, and where:

$$ϕ = ⌈ \begin{matrix}{y}_{past} ( k ) \\ {u}_{past} ( k )\end{matrix} ⌉ θ ( k ) = ⌈ \begin{matrix}{a}^{T} \\ {b}^{T}\end{matrix} ⌉$$

Now, if non-manipulated variables u(k)ₙₘ such as power consumption (e.g. current), water inlet temperature, etc. are added then equation (19) is transformed as shown in equation (20):

\hat{y}(k)=ayₚₐₛₜ(k)+vuₚₐₛₜ(k)+hu(k)+bₙₘu(k)ₚₐₛₜ₋ₙₘ+hₙₘu(k)ₙₘ (20)

where ŷ(k) is the output estimated behavior in the next iteration, ayₚₐₛₜ(k) is the past output behavior, vuₚₐₛₜ(k) is the past manipulated inputs behavior, hu(k) is the current manipulated inputs, bₙₘu(k)ₚₐₛₜ₋ₙₘ is the past non-manipulated inputs behavior (water temperature, power, etc.) and hₙₘu(k)ₙₘ is the current non-manipulated inputs behavior.

If the “j” non-manipulated variable has a discrete delay of order “dⱼ”, then the first “dⱼ” elements of the coefficients associated to that variable within hₙₘ will be close to 0. Hence, If the value of “dⱼ” is known, then the following correction can be made to the previous linear model:

\hat{y}(k)=ayₚₐₛₜ(k)+buₚₐₛₜ(k)+hu(k)+bₘₙ^{d}uₚₐₛₜ₋ₙₘ(k−d)+hₙₘ^{d}uₙₘ(k−d) (21)

where bₙₘ^{d} and hₙₘ^{d} are matrices containing elements which together (in absolute value) are farther from zero than the first dⱼ elements of hₙₘ and d contains information on all of the delays of the non-manipulated variables (some of them possibly zero):

$$d = ⌈ \begin{matrix}{d}_{1} \\ ⋮\end{matrix} ⌉$$

This modification creates an effect in the predictive equation shown as equation (4) above, which will be replaced by the following equation:

\hat{y}(k+γ|k)=Ayₚₐₛₜ(k)+Buₚₐₛₜ(k)+Hu_{future}(k)+Hₙₘ^{d}uₚₐₛₜ₋ₙₘ^{d}(k−d)+Hₙₘ^{p}uₙₘ^{p}(k−d)+Hₙₘ^{f}uₙₘ^{f}(k−d) (22)

where ŷ(k) is the output estimated behavior in the next iteration, ayₚₐₛₜ(k) is the past output behavior, Buₚₐₛₜ(k) is the past manipulated inputs behavior, Hu_{future}(k) is the current and future manipulated inputs, Hₙₘ^{d}uₚₐₛₜ₋ₙₘ^{d}(k−d) is the past non-manipulated inputs considering delay, Hₙₘ^{p}uₙₘ^{p}(k−d) is the known non-manipulated inputs behavior considering delay and Hₙₘ^{f}uₙₘ^{f}(k−d) is the estimated non-manipulated inputs behavior considering delay.

Similarly, equation (5) above would be replaced by the following equation:

$$\hat{y} ( k + γ \vert k ) = {Ay}_{past} ( k ) + {Bu}_{past} ( k ) + {H}_{r} u ( k ) + G Δ {u}_{future} ( k ) + {H}_{nm}^{d} {u}_{past \text{-} nm}^{d} ( k - d ) + {H}_{nm}^{p} {u}_{nm}^{p} ( k - d ) + {H}_{nm}^{f} {u}_{nm}^{f} ( k - d ) where \text{:} \\ {u}_{past \text{-} nm}^{d} ( k - d ) = [ \begin{matrix}{u}_{1 - nm}^{d} ( k - {d}_{1} ) \\ ⋮ \\ {u}_{q - nm}^{d} ( k - {d}_{q} )\end{matrix} ] , \\ {u}_{j - nm}^{d} ( k - {d}_{j} ) = [ \begin{matrix}{u}_{j} ( k - {d}_{j} ) \\ ⋮ \\ {u}_{j} ( k - {d}_{j} - {b}_{j} )\end{matrix} ] \\ {u}_{nm}^{p} ( k - d ) = [ \begin{matrix}{u}_{1 - nm}^{p} ( k - {d}_{1} ) \\ ⋮ \\ {u}_{q - nm}^{p} ( k - {d}_{q} )\end{matrix} ] , \\ {u}_{j - nm}^{p} ( k - {d}_{j} ) = [ \begin{matrix}{u}_{j} ( k - {d}_{j} + min ( {d}_{j} , γ ) ) \\ ⋮ \\ {u}_{j} ( k - {d}_{j} + 1 )\end{matrix} ] \qquad ( 23 )$$

Note that uₙₘ^{p}(k−d) are known values, not captured in the system model, but considered in the predictive equation that will affect the future behavior of the system.

$${u}_{nm}^{f} ( k - d ) = [ \begin{matrix}{u}_{1 - nm}^{f} ( k - {d}_{1} ) \\ ⋮ \\ {u}_{q - nm}^{f} ( k - {d}_{q} )\end{matrix} ] , \\ {u}_{j - nm}^{f} ( k - {d}_{j} ) = [ \begin{matrix}{u}_{j} ( k + γ - {d}_{j} ) \\ ⋮ \\ {u}_{j} ( k + 1 )\end{matrix} ]$$

If dᵢ is equal to 0 then up uᵢ₋ₙₘ^{p}(k−dⱼ) is merely an empty null space that should not be considered on uₙₘ^{p}(k−d). Also, if dᵢ≥γ then of uⱼ₋ₙₘ^{f}(k−dⱼ) is merely a null space that should not be considered on uₙₘ^{f}(k−d).

While the solution to equation (7) will remain unchanged, equation (8) will be replaced by:

Δu_{future-m}(k)=(G^{T}QG+R)⁻¹G^{T}Q(w−Ayₚₐₛₜ(k)−Buₚₐₛₜ(k) Hᵣu(k)−Hₙₘ^{d}uₚₐₛₜ₋ₙₘ^{d}(k−d)−Hₙₘ^{p}uₙₘ^{p}(k−d)−Hₙₘ^{f}uₙₘ^{f}(k−d)) (24)

Equation (11) will be replaced by:

g_{γ}Δu(k+γ)=w_{γ}a_{γ}yₚₐₛₜ(k)−b_{γ}uₚₐₛₜ(k)−g_{γ}u(k)−h_{nm-γ}^{d}uₚₐₛₜ₋ₙₘ^{d}(k−d)−h_{nm-γ}^{p}uₙₘ^{p}(k−d)−h_{nm-γ}^{f}uₙₘ^{f}(k−d) (25)

Additionally, equation (12) will be replaced by:

$$Δ u ( k + γ ) = \frac{{ℊ}_{γ}^{T}}{{ℊ}_{γ} {ℊ}_{γ}^{T}} ( {w}_{γ} - {a}_{γ} {y}_{past} ( k ) - {b}_{γ} {u}_{past} ( k ) - {ℊ}_{γ} u ( k ) - {h}_{nm - γ}^{d} {u}_{past \text{-} nm}^{d} ( k - d ) - {h}_{nm \text{-} γ}^{p} {u}_{nm}^{p} ( k - d ) - {h}_{nm \text{-} γ}^{f} {u}_{nm}^{f} ( k - d ) ) \qquad ( 26 )$$

Moreover, the expression (w_{γ}a_{γ}yₚₐₛₜ(k)−b_{yγ}uₚₐₛₜ(k)−g_{γ}u(k)), which had been denoted above as τ_{γ}, will be replaced by:

w_{γ}−a_{γ}yₚₐₛₜ(k)−b_{γ}uₚₐₛₜ(k)−h_{nm-γ}^{d}uₚₐₛₜ₋ₙₘ^{d}(k−d)−h_{nm-γ}^{p}uₙₘ^{p}(k−d)−h_{nm- γ}^{f}uₙₘ^{f}(k−d)

The constraint vᵢ=SAT(aᵢyₚₐₛₜ(k)+bᵢuₚₐₛₜ(k)+gᵢu(k),yₘᵢₙ, yₘₐₓ) is now replaced by:

vᵢ=SAT(aᵢyₚₐₛₜ(k)+bᵢuₚₐₛₜ(k)+gᵢu(k)+hₙₘ₋ᵢ^{d}uₚₐₛₜ₋ₙₘ^{d}(k−d)+hₙₘ₋ᵢ^{p}uₙₘ^{p}(k−d)+hₙₘ₋ᵢ^{f}uₙₘ^{f}(k−d), yₘᵢₙ, yₘₐₓ) (27)

The above modified equations can, like equations (11) and (12) above, be solved analytically using suitable software tools, such as those offered commercially under the trademark MATLAB®, or implemented in a suitable programming language, such as Python.

If dⱼ is unknown but expected to have a fixed value or only small variations, a value can be determined experimentally, possibly with periodic updates to detect changes in conditions. If dⱼ is expected to change over time, an algorithm can be used to detect and/or model the delay.

The above-described approach to including a delayed-effect variable as a further input to the thermal system model of an APC is not limited to current and proxies therefor. For example, where the equipment being cooled is information technology equipment such as servers, a projected server workload may also be used as a further input to the thermal system model of an APC according to the present disclosure. Signals representing current and its proxies (“current signals”) and signals representing projected server workload (“processing workload signals”) can be characterized broadly as a “workload signals”.

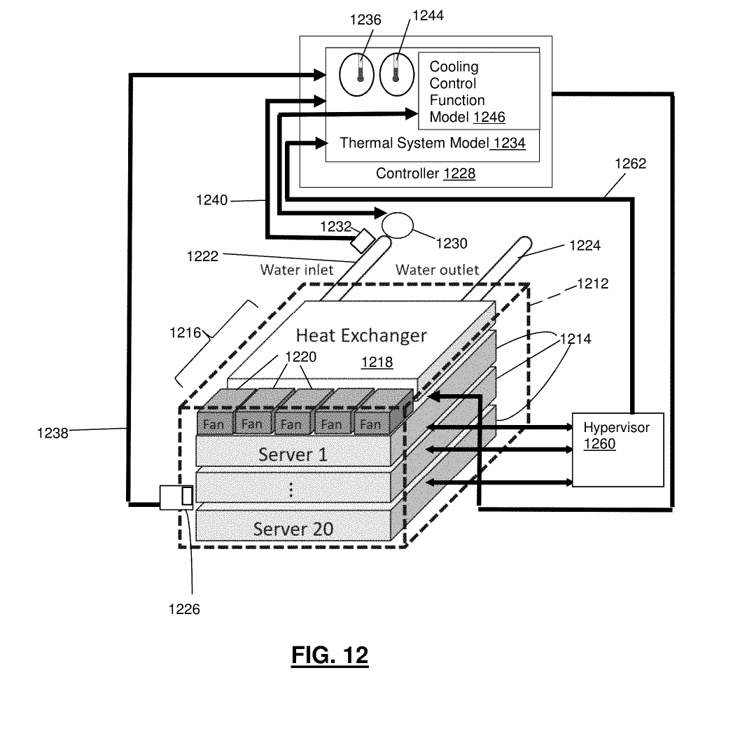

FIG. 12 shows an arrangement similar to FIG. 1, with like reference numerals denoting like features, except with the prefix “12”. A hypervisor 1260 controls processing workload assigned to the servers 1214 on the rack 1212 (as well as to other servers on other racks, not shown) and provides a processing workload signal 1262 which is received at the controller 1228. The processing workload signal 1262 represents a workload that will be assigned to the equipment (servers 1214 in this case) cooled by the cooling unit 1216, and is a further input to the thermal system model 1234. An increase or decrease in workload can be expected to result, after a delay, in a corresponding increase or decrease in temperature.

Where the equipment is servers 1234 or similar information technology equipment, the processing workload signal 1262 may merely indicate the workload assigned to the servers 1214 in the rack 1212 as a collective, or may be more granular. For example, if the thermal system model 1234 is sensitive to heat output from individual servers (e.g. there may be temperature sensors for each server or subsets of servers), the processing workload signal 1262 may indicate workloads for individual servers or subsets of servers in the rack.

While described in the context of information technology equipment such as servers, the use of projected future workload as an input to the thermal system model can be extended to other contexts as well.

Optionally, both a current signal and a processing workload signal may be used as inputs to the thermal system model.

### Method and Implementation

Current and its proxies, and projected server workload, are both examples of delayed-effect variables. A delayed-effect variable is one whose impact on the temperature of the equipment to be cooled is subject to potential delay and, unlike the gas coolant flow rate and liquid coolant flow rate, is not manipulated by the controller. The above-described mathematical approaches are not limited to “workload signals” such as current and projected server workload, but can be applied in respect of delayed-effect variables more generally. In this regard, a signal received by the controller and representing a delayed-effect variable associated with the equipment to be cooled is referred to as a “delayed-effect variable signal”.

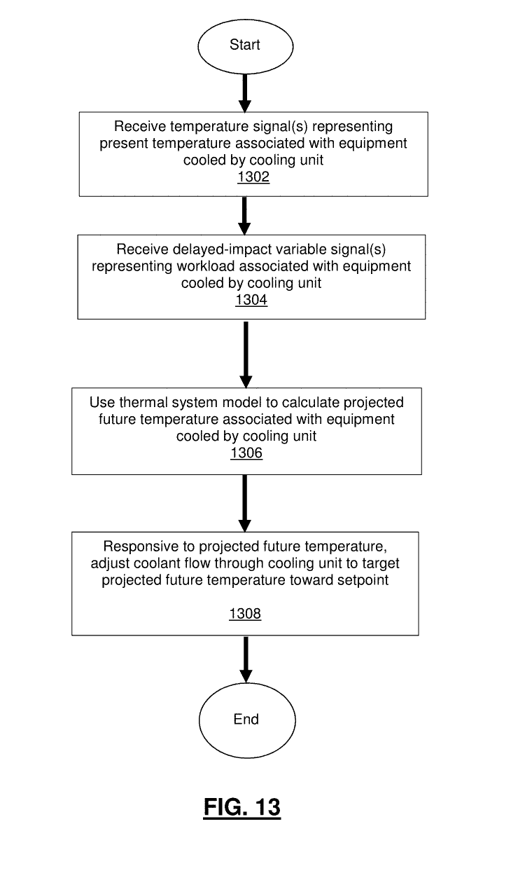

Reference is now made to FIG. 13, in which a method 1300 for controlling operational parameters of a cooling unit is shown schematically in flow chart form. The method 1300 would be executed by a controller of a cooling unit, wherein a coolant flow through the cooling unit comprises a liquid coolant flow through the cooling unit and a gas coolant flow through the cooling unit.

At step 1302, the controller receives a temperature signal representing a present temperature associated with equipment cooled by the cooling unit. At step 1304, the controller receives at least one delayed-effect variable signal representing a delayed-effect variable associated with the equipment cooled by the cooling unit. The delayed-effect variable signal(s) may be, for example, a workload signal such as a processing workload signal representing an indication of a workload that will be assigned to the equipment cooled by the cooling unit (e.g. from a hypervisor controlling information technology equipment), or a current signal representing a current drawn by the equipment cooled by the cooling unit, or a combination (e.g. two distinct signals or a signal representing a mathematic combination of the two signals). At step 1306, the controller, using a thermal system model to which the temperature signal, the delayed-effect variable signal(s), the liquid coolant flow and the gas coolant flow are inputs, calculates a projected future temperature associated with the equipment cooled by the cooling unit. The thermal system model may include a cooling control function model for selectively cooperating the liquid coolant flow and the gas coolant flow to target the set-point according to an optimization parameter, for example energy consumption or speed of set-point targeting. The thermal system model may be a static model, but is preferably an adaptive model and particularly preferably is an adaptive predictive model of the type described above.

At step 1308, responsive to the projected future temperature, the controller adjusts coolant flow through the cooling unit to target the projected future temperature toward a set-point by adjusting the liquid coolant flow and the gas coolant flow.

As can be seen from the above description, the cooling technology described herein represent significantly more than merely using categories to organize, store and transmit information and organizing information through mathematical correlations. The apparatus and methods described herein are in fact an improvement to the technology of equipment cooling, as they may provide the ability to deal with time-varying systems, to transform infeasible solutions computed by the predictive formulation into feasible solutions when there is at least one, to cope with transitory adaptation to the system, to vary the learning rate associated with new data according to the dynamics of the system, and to avoid numerical instability when the adaptive algorithm faces low system excitation. These abilities of the technology facilitate efficient and effective cooling. Moreover, the technology is applied by using a particular machine, namely a cooling unit that includes heat exchanger with both a liquid coolant flow and a gas coolant flow. As such, the technology described herein is confined to cooling applications.

The present technology may be embodied within a system, a method, a computer program product or any combination thereof. The computer program product may include a computer readable storage medium or media having computer readable program instructions thereon for causing a processor to carry out aspects of the present technology. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing.

A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present technology may be assembler instructions, instruction-set-architecture (ISA) instructions, machine instructions, machine dependent instructions, microcode, firmware instructions, state-setting data, or either source code or object code written in any combination of one or more programming languages, including an object oriented programming language or a conventional procedural programming language. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to implement aspects of the present technology.

Aspects of the present technology have been described above with reference to flowchart illustrations and/or block diagrams of methods, apparatus (systems) and computer program products according to various embodiments. In this regard, the flowchart and block diagrams in the Figures illustrate the architecture, functionality, and operation of possible implementations of systems, methods and computer program products according to various embodiments of the present technology. For instance, each block in the flowchart or block diagrams may represent a module, segment, or portion of instructions, which comprises one or more executable instructions for implementing the specified logical function(s). It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Some specific examples of the foregoing may have been noted above but any such noted examples are not necessarily the only such examples. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It also will be understood that each block of the flowchart illustrations and/or block diagrams, and combinations of blocks in the flowchart illustrations and/or block diagrams, can be implemented by computer program instructions. These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. Thus, while an Arduino Mega was referenced as an illustrative controller, this is merely one illustrative example and not a limiting one; the term “controller” is intended to refer broadly to any device capable of executing the required processing.

These computer readable program instructions may also be stored in a computer readable storage medium that can direct a computer, other programmable data processing apparatus, or other devices to function in a particular manner, such that the instructions stored in the computer readable storage medium produce an article of manufacture including instructions which implement aspects of the functions/acts specified in the flowchart and/or block diagram block or blocks. The computer readable program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

Finally, the terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description has been presented for purposes of illustration and description, but is not intended to be exhaustive or limited to the form disclosed. Many modifications and variations will be apparent to those of ordinary skill in the art without departing from the scope of the claims. The embodiment was chosen and described in order to best explain the principles of the technology and the practical application, and to enable others of ordinary skill in the art to understand the technology for various embodiments with various modifications as are suited to the particular use contemplated.

One or more currently preferred embodiments have been described by way of example. It will be apparent to persons skilled in the art that a number of variations and modifications can be made without departing from the scope of the claims.

What is claimed is:

1. A method for controlling operational parameters of a cooling unit, wherein a coolant flow through the cooling unit comprises:
a liquid coolant flow through the cooling unit; and
a gas coolant flow through the cooling unit;
the method comprising:
receiving, at a controller for the cooling unit, at least one temperature signal representing a present temperature associated with equipment cooled by the cooling unit;
receiving, at the controller, at least one delayed-effect variable signal representing a delayed-effect variable associated with equipment cooled by the cooling unit;
calculating, by the controller, using a thermal system model to which the at least one temperature signal, the at least one delayed-effect variable signal, the liquid coolant flow and the gas coolant flow are inputs, a projected future temperature associated with the equipment cooled by the cooling unit; and
responsive to the projected future temperature, adjusting coolant flow through the cooling unit to target the projected future temperature toward a set-point.

2. The method of claim 1, wherein the thermal system model includes a cooling control function model for selectively cooperating the liquid coolant flow and the gas coolant flow to target the set-point according to an optimization parameter.

3. The method of claim 2, wherein the optimization parameter is one of energy consumption and speed of set-point targeting.

4. The method of claim 1, wherein the thermal system model is a static model.

5. The method of claim 1, wherein the thermal system model is an adaptive model.

6. The method of claim 1, wherein:
the equipment is information technology equipment; and
the at least one delayed-effect variable signal comprises a processing workload signal representing an indication of a workload that will be assigned to the information technology equipment.

7. The method of claim 1, wherein the at least one delayed-effect variable signal comprises a current signal representing a current drawn by the equipment cooled by the cooling unit.

8. A cooling unit, comprising:
a heat exchanger;
at least one liquid flow control element adapted to control flow of liquid coolant through the heat exchanger;
at least one gas flow control element adapted to control flow of gas coolant across the heat exchanger;
at least one temperature sensor adapted to sense a temperature associated with equipment to be cooled by the cooling unit; and
a controller, wherein:
the controller is coupled to the at least one temperature sensor to receive at least one temperature signal representing the temperature associated with the equipment to be cooled by the cooling unit;
the controller is adapted to receive at least one delayed-effect variable signal representing a delayed-effect variable associated with equipment cooled by the cooling unit;
the controller is coupled to the at least one liquid flow control element and adapted to manipulate the at least one liquid flow control element to control the flow of liquid coolant through the heat exchanger;
the controller is coupled to the at least one gas flow control element and adapted to manipulate the at least one gas flow control element to control the flow of gas coolant across the heat exchanger;
wherein the controller is configured to:
calculate, using a thermal system model to which the at least one temperature signal, the at least one delayed-effect variable signal; the liquid coolant flow and the gas coolant flow are inputs, a projected future temperature associated with the equipment cooled by the cooling unit; and
responsive to the projected future temperature, adjust coolant flow through the cooling unit to target the projected future temperature toward a set-point.

9. The cooling unit of claim 8, wherein the thermal system model includes a cooling control function model for selectively cooperating the liquid coolant flow and the gas coolant flow to target the set-point according to an optimization parameter.

10. The cooling unit of claim 8, wherein the thermal system model is an adaptive model.

11. The cooling unit of claim 8, wherein:
the equipment is information technology equipment; and
the at least one delayed-effect variable signal comprises a processing workload signal representing an indication of a workload that will be assigned to the information technology equipment.

12. The cooling unit of claim 8, wherein the at least one delayed-effect variable signal comprises a current signal representing a current drawn by the equipment cooled by the cooling unit.

13. A computer program product comprising a tangible computer-readable medium carrying instructions which, when executed by a controller coupled to a cooling unit wherein a coolant flow through the cooling unit comprises a liquid coolant flow and a gas coolant flow across, cause the controller to control operational parameters of the cooling unit by:
receiving, at the controller, at least one temperature signal representing a present temperature associated with equipment cooled by the cooling unit;
receiving, at the controller, at least one delayed-effect variable signal representing a delayed-effect variable associated with equipment cooled by the cooling unit;
calculating, by the controller, using a thermal system model to which the at least one temperature signal, the at least one delayed-effect variable signal, the liquid coolant flow and the gas coolant flow are inputs, a projected future temperature associated with the equipment cooled by the cooling unit; and
responsive to the projected future temperature, adjusting coolant flow through the cooling unit to target the projected future temperature toward a set-point.

14. The computer program product of claim 13, wherein the thermal system model includes a cooling control function model for selectively cooperating the liquid coolant flow and the gas coolant flow to target the set-point according to an optimization parameter.

15. The computer program product of claim 14, wherein the optimization parameter is one of energy consumption and speed of set-point targeting.

16. The computer program product of claim 13, wherein the thermal system model is a static model.

17. The computer program product of claim 13, wherein the thermal system model is an adaptive model.

18. The computer program product of claim 13, wherein:
the equipment is information technology equipment; and
the at least one delayed-effect variable signal comprises a processing workload signal representing an indication of a workload that will be assigned to the information technology equipment.

19. The computer program product of claim 13, wherein the at least one delayed-effect variable signal comprises a current signal representing a current drawn by equipment to be cooled.
